(19) United States
(12) Patent Application Publication
(10) Pub. No.: US 2024/0332477 A1
(43) Pub. Date: Oct. 3, 2024

(54) DISPLAY APPARATUS

(71) Applicant: LG Display Co., Ltd., Seoul (KR)

(72) Inventors: JeongJo LEE, Paju-si (KR); HanSeok KIM, Paju-si (KR); TaeYoung JUNG, Paju-si (KR)

(21) Appl. No.: 18/435,504

(22) Filed: Feb. 7, 2024

(30) Foreign Application Priority Data
Mar. 31, 2023 (KR) 10-2023-0043064

(51) Int. Cl. H01L 33/64; H01L 25/16; H05K 7/20

(52) U.S. Cl. CPC H01L 33/642; H01L 25/167; H01L 33/648; H05K 7/2099

(57) ABSTRACT

The present disclosure relates to a display apparatus. A display apparatus according to an embodiment of the present disclosure includes a display panel configured to display images, a heat dissipation member disposed on one side of the display panel, and a printed circuit board disposed on one side of the heat dissipation member. The heat dissipation member includes a first portion overlapping the printed circuit board, and a second portion disposed in an area spaced apart from the printed circuit board at a certain interval.

### CROSS-REFERENCE TO RELATED APPLICATION

This application claims priority to and the benefit of Korean Patent Application No. 10-2023-0043064, filed Mar. 31, 2023, the disclosure of which is incorporated herein by reference in its entirety.

### BACKGROUND

### Technical Field

The present disclosure relates to a display apparatus, and more specifically, to a display apparatus using a light emitting diode (LED).

### Description of the Related Art

Recent display apparatuses capable of displaying a variety of information and interacting with a user who views the information at the same time are required to have various sizes, various forms, and various functions.

These display apparatuses may include a liquid crystal display (LCD) device, an electrophoretic display (FPD) device, and a light emitting diode display (LED) device, etc.

Recently, a display apparatus including a light emitting diode (hereinafter referred to as “LED”) have been attracted attention as a next-generation display apparatus. Since the LEDs are made of inorganic materials, not organic materials, they have a longer lifespan than a liquid crystal display apparatus or organic light emitting display apparatus because of their excellent reliability. In addition, the LEDs not only have a fast lighting speed, but also have excellent luminous efficiency, strong impact resistance, so they may have excellent stability, and may display high-brightness images.

### BRIEF SUMMARY

The present disclosure provides a display apparatus including a heat dissipation member to solve a heat generation problem of the display apparatus.

The present disclosure provides a display apparatus including a heat dissipation member in order to reduce a temperature deviation depending on a position of the display apparatus.

The present disclosure provides a display apparatus capable of evenly diffusing heat generated from a printed circuit board throughout a display panel.

The present disclosure provides a display apparatus that reduces a temperature difference between an area on which the printed circuit board is disposed and an area on which the printed circuit board is not disposed, thereby minimizing the appearance of spots or color differences.

According to an embodiment of the present disclosure, a display apparatus may include a display panel configured to display images, a heat dissipation member disposed on one side of the display panel, and a printed circuit board disposed on one side of the heat dissipation member, wherein the heat dissipation member may include a first portion overlapping the printed circuit board, and a second portion disposed in an area spaced apart from the printed circuit board at a certain interval.

According to another embodiment of the present disclosure, a display apparatus may include a plurality of display modules disposed on the same plane, wherein each of the display modules may include a display panel having a front surface on which a plurality of light emitting elements are disposed, and a rear surface opposite the front surface, a printed circuit board disposed on the rear surface of the display panel, and a heat exchange tube that at least partially overlaps the printed circuit board

According to the embodiment of the present disclosure, the display apparatus may include a heat dissipation member, thereby solving a heat generation problem caused by driving the display apparatus.

According to the embodiment of the present disclosure, the display apparatus may include a heat dissipation member, thereby reducing a temperature deviation depending on a position of the display apparatus.

According to the embodiment of the present disclosure, the display apparatus may minimize heat concentration in a partial area or a specific area of the display panel by diffusing heat generated from a printed circuit board throughout a display panel.

According to the embodiment of the present disclosure, the display apparatus may improve display quality by minimizing visible spots or color differences due to the temperature deviation in the display panel.

Effects which can be achieved by the present disclosure are not limited to the above-mentioned effects. That is, other objects that are not mentioned may be obviously understood by those skilled in the art to which the present disclosure pertains from the following description.

### BRIEF DESCRIPTION OF THE SEVERAL VIEWS OF THE DRAWINGS

The above and other objects, features, and advantages of the present disclosure will become more apparent to those of ordinary skill in the art by describing example embodiments thereof in detail with reference to the attached drawings, in which:

FIG. 1 is a diagram illustrating a temperature distribution of a display panel in an example of a display apparatus in which heat dissipation measures of a display panel are not optimized;

FIG. 2 is an exploded perspective view of a display apparatus according to an embodiment of the present disclosure;

FIG. 3 is a plan view of a rear surface of a display apparatus according to an embodiment of the present disclosure;

FIG. 4 is a cross-sectional view taken along line I-I′ of FIG. 2 according to an embodiment of the present disclosure;

FIG. 5A is a cross-sectional view taken along line II-II′ of FIG. 2 according to an embodiment of the present disclosure;

FIG. 5B is a cross-sectional view taken along line II-II′ of FIG. 2 according to another embodiment of the present disclosure;

FIG. 6 is a cross-sectional view taken along line III-III′ of FIG. 2 according to an embodiment of the present disclosure;

FIG. 7 is a simulation result showing a temperature of a display apparatus according to an embodiment of the present disclosure;

FIG. 8 is a plan view of a display apparatus including a heat dissipation member according to another embodiment of the present disclosure;

FIG. 9 is a plan view of a display apparatus including a heat dissipation member according to another embodiment of the present disclosure;

FIG. 10 is a plan view of a display apparatus including a heat dissipation member according to another embodiment of the present disclosure;

FIG. 11 is a block diagram illustrating a configuration of a display panel according to an embodiment of the present disclosure;

FIG. 12 is a cross-sectional view illustrating a printed circuit board and a side wiring disposed at the outermost side of a display panel according to an embodiment of the present disclosure;

FIG. 13 is a perspective view of a tiled display apparatus according to an embodiment of the present disclosure;

FIG. 14 is a block diagram showing control boards connected to a plurality of printed circuit boards and a system board connected to the control boards according to an embodiment of the present disclosure;

FIG. 15 is a plan view illustrating a planar structure of a display panel according to an embodiment of the present disclosure; and

FIG. 16 is a cross-sectional view illustrating a cross-sectional structure of a display panel according to an embodiment of the present disclosure.

### DETAILED DESCRIPTION

The advantages and features of the present disclosure, and methods for achieving them will become apparent from the embodiments described below in detail in conjunction with the accompanying drawings. However, the present disclosure is not limited to the embodiments disclosed herein, but may be implemented in various different forms; rather, the present embodiments are provided to make the disclosure of the present disclosure complete and to enable those skilled in the art to fully comprehend the scope of the present disclosure.

The shapes, sizes, proportions, angles, numbers, and the like of elements shown in the drawings to illustrate embodiments of the present disclosure are merely illustrative and are not intended to be limiting. Identical reference numerals may designate identical components throughout the description. Further, in describing the present disclosure, detailed descriptions of well-known technologies may be omitted so as not to obscure the essence of the present disclosure. Terms such as “comprising”, “including”, “having”, and “consisting of” as used herein are generally intended to allow for the addition of other components, unless the terms are used with the term “only”. References to components of a singular noun include the plural of that noun, unless specifically stated otherwise.

When describing components, they are interpreted to include margins of error even when not explicit stated.

When describing the positional relationship, for example, if the positional relationship of the two parts is described as “on the top”, “above”, “below”, “next to”, etc., one or more other parts may be located between the two parts unless “directly” is used.

When describing a temporal contextual relationship, such as “after”, “following”, “next to”, or “before”, it may also include non-contiguous cases unless “immediately” or “directly” is used.

The first, second, etc., are used to describe various components, but these components are not limited by these terms. These terms are used only to distinguish one component from another. Therefore, the first component referred to below may be a second component within the technical spirit of the present disclosure.

Terms such as first, second, A, B, (a), (b), and the like may be used to describe elements of the embodiments of the present disclosure. Such terms are intended only to distinguish one component from another and are not intended to define the nature, sequence, order, or number of such components. When a component is described as “connected” “coupled” or “attached” to another component, it is to be understood that the component may be directly connected or attached to the other component, but that there may also be other components “interposed” between the respective components which may be indirectly connected or attached where not specifically stated.

It should be understood that the term “at least one” includes all possible combinations of one or more related components. For example, the meaning of “at least one of the first, second, and third components” includes not only the first, second, or third component, but also any combination of two or more of the first, second, and third components.

As used herein, “a device” may include a display apparatus, such as a liquid crystal module (LCM) or an organic light emitting display (OLED) module, which includes a display panel and a driver for driving the display panel. It may also include a set electronic device or a set device, such as a laptop computer, a television set, a computer monitor, a vehicle or an automotive device, or an equipment device including another form of vehicle, and a mobile electronic device, such as a smart phone or an electronic pad and the like, which is a complete product or finished product including LCMs, OLED modules, and the like.

Accordingly, the apparatus or device as described herein may include a display apparatus itself, such as an LCM or OLED module, and an application product, as well as a set device, an end user device that includes the LCM or the OLED module.

Furthermore, in some embodiments, the LCM and OLED module consisting the display panel and the driver may be expressed as a “display apparatus”, the electronic device may be expressed as a finished product including the LCM and OLED module that may be expressed as a “set device”. For example, a display apparatus may include a liquid crystal display (LCD) panel or an organic light emitting display (OLED) panel, and a source PCB (printed circuit board) which is a control part for driving the display panel. The set device may further include a set PCB, which is a set control part electrically connected to the source PCB to drive the entire set device.

The display panel used in embodiments of the present disclosure may be any type of display panel, including, but not limited to, liquid crystal display panels, organic light emitting diode (OLED) display panels, and electroluminescent display panels. The display panel applicable to the display apparatus according to embodiments of the present disclosure is not limited to the shape or size of the display panel.

Each of the features of the various embodiments described herein may be coupled or combined with one another in whole or in part, and may be technologically interlocked and operated in various ways, and each of the embodiments may be carried out independently or in conjunction with one another.

Hereinafter, embodiments of the present disclosure are illustrated by way of the accompanying drawings and examples. The dimensions of the components shown in the drawings are to scale for illustrative purposes only and are not to scale with the actual components shown in the drawings.

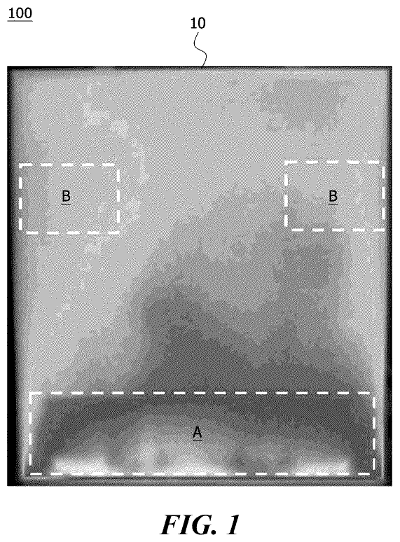

FIG. 1 is a diagram illustrating a temperature distribution of a display panel in an example of a display apparatus in which heat dissipation measures of a display panel are not optimized.

Referring to FIG. 1, a printed circuit board may be disposed on one side of the display apparatus 100. The printed circuit board may be a metal pattern to which external modules, such as a printed circuit board, a flexible printed circuit board (FPCB), and a chip on film (COF) are bonded.

Various chips for driving the display apparatuses are disposed on the printed circuit board of the display apparatus. For example, on a printed circuit board, a device used to make various voltages, such as a high-potential power supply source, a low-potential power supply source, and a reference power supply source, for example, an IC chip may be disposed. Meanwhile, when driving the display apparatus, heat may be generated from a chip disposed on the printed circuit board. For example, the heat may be generated by various chips such as IC FETs or buck ICs that generate high-potential voltages, such as power management integrated circuits (PMIC), which are disposed on the printed circuit board. Accordingly, the heat is concentrated in an area on which the printed circuit board is disposed, for example, a lower area of the display panel 10, so the overall temperature deviation of the display panel 10 may be increased. If there is a temperature deviation for each area of the display panel 10, the spots may be visible in the display panel 10, color differences may occur, and display quality may deteriorate.

Referring to FIG. 1, it may be seen that a temperature distribution of the display apparatus 100 is different depending on a position.

In FIG. 1, a part with dark contrast represents a high temperature, and a part with light contrast represents a low temperature. The display apparatus 100 may have a first region A with a high temperature and a second region B with a low temperature depending on the temperature of the display apparatus 100. For example, the first region A is a region on which the printed circuit board is disposed and represents a high temperature, for example, the temperature was measured to be about 55° C. The second region B is a region spaced apart from the printed circuit board at a certain interval, and the temperature was measured to be about 40° C. 55° C. measured in the first region A may cause low-temperature burns to the user. For example, the low-temperature burns are caused by a lower temperature than a temperature that causes burns, but occur when exposed to a temperature above 40° C. for a relatively long time, because they are not recognized early compared to burns caused by a high temperature.

Additionally, it may be confirmed that the display apparatus 100 has a temperature deviation of about 15° C. in the first region A and the second region B. Heat is concentrated in the first region A, which is the lower area on which the printed circuit board is disposed, and so the overall temperature deviation of the display panel 10 may be increased. If there is a temperature deviation in an area of the display panel 10, the spots may be visible in the display panel 10 or color differences may occur, which may deteriorate display quality.

Various experiments were conducted to reduce the temperature deviation depending on the position or area of the display apparatus 100, and through the various experiments, a new display apparatus that may solve the problems of heat generation of the display apparatus and temperature deviation within the display apparatus was invented.

The display apparatus 100 according to an embodiment of the present disclosure may reduce the overall temperature deviation of the display panel 10 by disposing a heat dissipation member in a specific area where the high temperature occurs in the display panel 10, for example, an area overlapping the printed circuit board. The heat dissipation member may be disposed between the display panel 10 and the printed circuit board to uniformly implement the overall temperature of the display apparatus 100. For example, the heat dissipation member may be disposed in contact with the surface of the printed circuit board to evenly spread heat generated from the printed circuit board disposed in the lower region of the display panel 10 to the middle and upper regions of the display panel 10. As a result, the heat generated from the printed circuit board may be spread to the front of the display apparatus, making the overall temperature of the display apparatus uniform, thereby minimizing spots and color differences and improving display quality.

Hereinafter, various embodiments of the present disclosure will be described in detail with reference to the drawings.

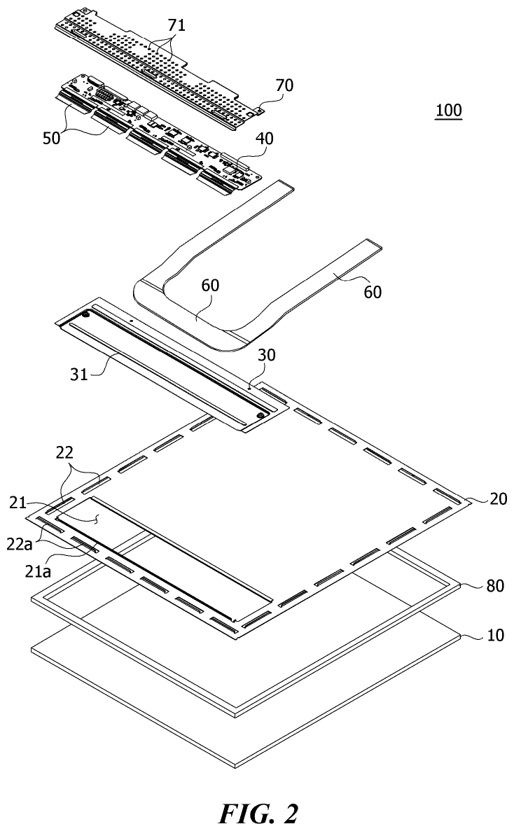

FIG. 2 is an exploded perspective view of a display apparatus according to an embodiment of the present disclosure.

Referring to FIG. 2, a display apparatus according to an embodiment of the present disclosure may include a display panel 10, a printed circuit board 40, and a heat dissipation member 60.

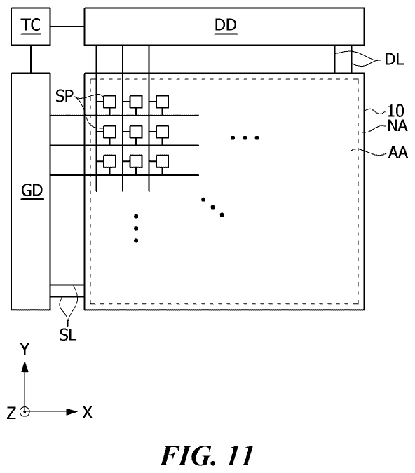

The display panel 10 may display images or videos in a display apparatus. The display panel according to the present disclosure may include a light emitting diode (LED). The components of the display panel 10 will be described in detail later with reference to FIGS. 11 to 16.

A cover bottom 20 may be disposed on the rear surface of the display panel 10. The cover bottom 20 may support and protect the display panel 10 on the rear surface of the display panel 10. The cover bottom 20 has a shape that corresponds to the planar shape of the display panel 10 and may cover the display panel 10. The cover bottom 20 may be made of a material having rigidity and high thermal conductivity. For example, the cover bottom 20 may be made of a metal material such as aluminum (Al), copper (Cu), zinc (Zn), silver (Ag), gold (Au), iron (Fe), stainless steel (SUS), or invar, or a material such as plastic, and the embodiments of the present disclosure are not limited thereto. For example, the cover bottom 20 may be a first plate, and the embodiments of the present disclosure are not limited thereto.

The cover bottom 20 may include a first opening 21 and a plurality of second openings 22.

The first opening 21 of the cover bottom 20 may be disposed to correspond to flexible film 50 and the printed circuit board 40. The first opening 21 may be located in an area where the plurality of flexible films 50 are bonded to the display panel 10. For example, the plurality of flexible films 50 may be bonded to an area adjacent to an edge on one side of the display panel 10, and the first opening 21 may also be formed to correspond to an area adjacent to an edge of one side of the display panel 10.

A first protrusion 21a may be disposed on the edge of the first opening 21. The first protrusion 21a may be disposed on an edge of one side adjacent to an edge of one side of the display panel 10 among the edges of the first opening 21. The first protrusion 21a may be disposed on an edge closest to an edge of a lower side of the display panel 10 among the edges of the first opening 21. The first protrusion 21a may be disposed to protrude in a direction perpendicular to the rear surface of the cover bottom 20 from the edge of one side of the first opening 21. The first protrusion 21a engages with a cover shield 70, which will be described later, to limit the movement of the cover shield 70 and guide the position of the cover shield 70.

The plurality of second openings 22 of the cover bottom 20 may be disposed along the edge of the cover bottom 20. The plurality of second openings 22 may be disposed parallel to the edge of the cover bottom 20. A plurality of second protrusions 22a may be further included on one surface of a plurality of second openings 22.

The plurality of second protrusions 22a may be used to couple the display apparatus 100 to a cabinet. The display apparatus 100 may be fixed to the cabinet in the form of a tile by the plurality of second protrusions 22a, thereby forming a tiled display apparatus. The plurality of second protrusions 22a may be a portion that protrudes from an edge of one side of the plurality of second openings 22 onto the rear surface of the cover bottom 20. The plurality of second protrusions 22a may be a portion in which a portion of the cover bottom 20 is bent in a direction perpendicular to the rear surface of the cover bottom 20. For example, the plurality of second protrusions 22a may have an ‘L’ shaped cross-section, but embodiments of the present disclosure are not limited thereto.

The second protrusion 22a may be formed by cutting a portion of the cover bottom 20 and bending the cover bottom 20. When the plurality of second protrusions 22a are formed, a plurality of second openings 22 may be formed in a cut portion of the cover bottom 20. Accordingly, the second protrusions 22a may be disposed on the edges of the plurality of second openings 22. For example, the second protrusion 22a may be disposed on an edge disposed parallel to the edge of the cover bottom 20 among the edges of the second opening 22.

A plate bottom 30 may be disposed on the rear surface of the display panel 10 and the cover bottom 20. The plate bottom 30 may dissipate heat generated by the printed circuit board 40 by distributing the heat. The plate bottom 30 prevents the printed circuit board 40 from directly contacting the display panel 10, thereby minimizing the heat of the printed circuit board 40 from being concentrated on a specific area of the display panel 10. The printed circuit board 40 includes a plurality of components, and among the plurality of components, some driving chips that generate a lot of heat may be disposed thereon. The plate bottom 30 may distribute heat generated from some driving chips of the printed circuit board 40 throughout the plate bottom 30, so that the heat is not concentrated on some areas of the display panel 10 adjacent to the driving chip, and the overall temperature deviation of the display panel is reduced. The plate bottom 30 may be a second plate, and embodiments of the present disclosure are not limited thereto.

The plate bottom 30 includes a bead 31. The bead 31 is a portion that protrudes from one surface of the plate bottom 30 toward the printed circuit board 40, and may increase the rigidity of the plate bottom 30 while supporting the printed circuit board 40. The bead 31 may be in direct contact with the printed circuit board 40, and the heat generated from the printed circuit board 40 may be distributed throughout the plate bottom 30 through the bead 31.

A portion of the plate bottom 30 may cover the cover bottom 20, and another portion of the plate bottom 30 may be disposed in the first opening 21 of the cover bottom 20. The plate bottom 30 may pass through the first opening 21 of the cover bottom 20 and support the printed circuit board 40 disposed on the cover bottom 20.

The plate bottom 30 may be disposed to extend outside the first opening 21 and overlap the rear surface of the cover bottom 20. For example, the plate bottom 30 may be disposed to extend from the first opening 21 toward the center of the display panel 10 and overlap the rear surface of the cover bottom 20. The plate bottom 30 may be omitted depending on the structure and type of the display apparatus 100.

A heat dissipation member 60 may be disposed on the rear surface of the cover bottom 20 or the plate bottom 30. The heat dissipation member 60 may be disposed between the cover bottom 20 and the printed circuit board 40 or between the plate bottom 30 and the printed circuit board 40.

The heat dissipation member 60 may distribute heat generated from the printed circuit board 40 by distributing the heat. For example, the heat dissipation member 60 may be disposed on a first region A having a high temperature and a second region B having a low temperature in the display apparatus 100.

According to an embodiment of the present disclosure, the plate bottom 30 prevents the printed circuit board 40 from directly contacting the display panel 10, thereby minimizing the heat of the printed circuit board 40 from being concentrated on a specific area of the display panel 10. The printed circuit board 40 includes a plurality of components, and among the plurality of components, some driving chips that generate a lot of heat may be disposed thereon. The plate bottom 30 may distribute heat generated from some driving chips of the printed circuit board 40 throughout the plate bottom 30, so that the heat is not concentrated on some areas of the display panel 10 adjacent to the driving chip, and the overall temperature deviation of the display panel is reduced.

The heat dissipation member 60 according to an embodiment of the present disclosure may be disposed over a first region A having a high temperature due to the printed circuit board 40 in the display apparatus 100 and a second region B having a low temperature in the display apparatus 100. The heat dissipation member 60 may prevent heat generated from the display apparatus 100 from being concentrated on a specific area, thereby reducing the overall temperature deviation of the display apparatus 100. The heat dissipation member 60 may be disposed between the display panel 10 and the printed circuit board 40 to make the overall temperature of the display panel 10 uniform. For example, the heat dissipation member 60 may be disposed to be in contact with the surface of the printed circuit board 40 and the surface of the display panel 10 to evenly spread heat generated from the printed circuit board (40) disposed on a lower region of the display panel 10 toward the middle and upper regions of the display panel 10. Accordingly, the heat generated from the printed circuit board 40 spreads to the front of the display panel 10 to uniformly implement the overall temperature of the display panel 10, thereby minimizing spots or color differences and improving display quality.

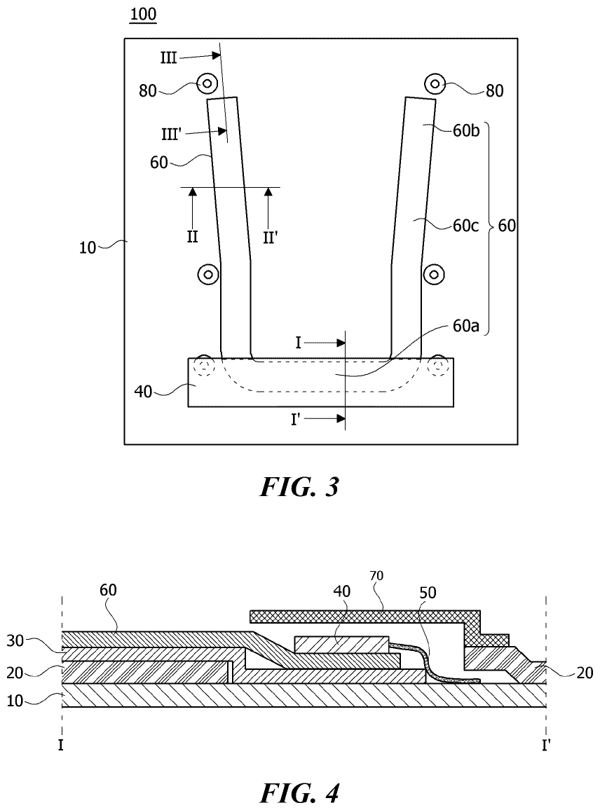

The heat dissipation member 60 will be described in detail later with reference to FIGS. 3 to 6.

The printed circuit board 40 may be disposed on the rear surface of the heat dissipation member 60 or the cover bottom 20. The printed circuit board 40 may be a component that supplies signals to the driving IC.

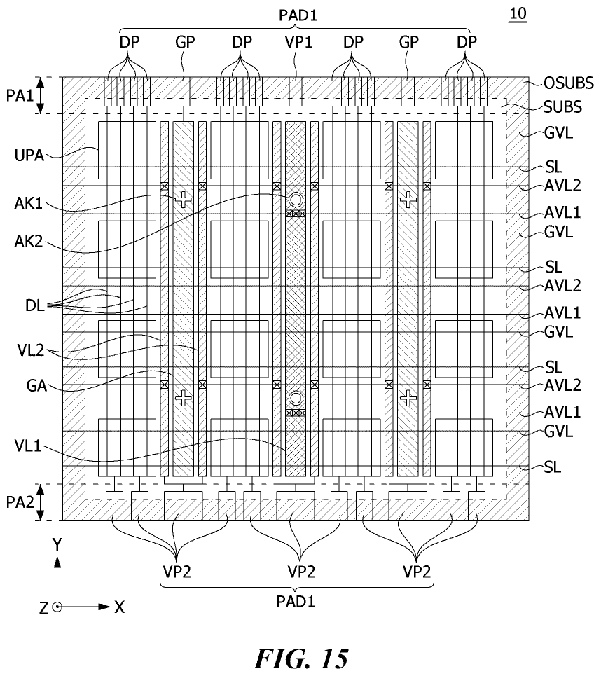

Various components may be disposed on the printed circuit board 40 to supply various signals to the driving IC. The flexible film 50 may be bonded to one surface of the printed circuit board 40. The flexible film 50 may be composed of a plurality of flexible films 50 and may be electrically connected to a plurality of second pad electrodes PAD2 shown in FIG. 15. The flexible film 50 is a film in which various components are disposed on a flexible base film to supply signals to sub-pixels (SP) and driving components, and may be electrically connected to the display panel 10.

A driving IC, such as a gate driver IC or a data driver IC, may be disposed on the flexible film 50. The driving IC may be a component that processes data for displaying an image and a driving signal for processing the same. The driving IC may be disposed in a method such as chip on glass (COG), chip on film (COF), or tape carrier package (TCP) according to a mounted method, and embodiments of the present disclosure are not limited thereto. However, for convenience of explanation, it has been described that the driving ICs are mounted on a plurality of flexible films 50 according to a chip-on-film method, but is not limited thereto.

Although FIG. 2 shows that there are five flexible films 50 and one printed circuit board 40, the number of flexible films 50 and printed circuit boards 40 may be varied depending on the design, but is not limited thereto.

A cover shield 70 may be disposed on the rear surfaces of the printed circuit board 40 and the cover bottom 20. The cover shield 70 may protect the printed circuit board 40 from external impact. The cover shield 70 is made of a material having rigidity and may protect the printed circuit board 40, but is not limited thereto. The cover shield 70 may be a shield member or a protection member, and the embodiments of the present disclosure are not limited thereto.

The cover shield 70 may be disposed on the rear surface of the cover bottom 20 to cover the printed circuit board 40. An edge of one side of the cover shield 70 may be bent toward the cover bottom 20 to be in contact with the outer surface of the first protrusion 21a. For example, the edge of one side of the cover shield 70 is bent in an ‘7’ shape and may be in contact with the outer surface of the first protrusion 21a of the cover bottom 20. Accordingly, the first protrusion 21a and a portion of one side of the cover shield 70 are engaged with each other, so that the movement of the cover shield 70 is restricted and the position of the cover shield 70 may be guided.

The cover shield 70 may include one or more heat dissipation holes (or holes) 71. A plurality of heat dissipation holes 181 may be disposed in most areas of the cover shield 70. The plurality of heat dissipation holes 71 may dissipate heat generated from the printed circuit board 40 to the outside of the cover shield 70. Among the plurality of components on the printed circuit board 40, some driving chips that generate a lot of heat may be exposed from the cover shield 70. By exposing some of the driving chips that generate a lot of heat from the cover shield 70, the heat generated from the driving chips may be efficiently dissipated. Accordingly, an additional groove or hole may be formed in a portion of the cover shield 70 depending on a position of the driving chip that generates a lot of heat.

An adhesive member 80 may be disposed between the cover bottom 20 and the display panel 10. The adhesive member 80 may be made of an adhesive material to secure the cover bottom 20 to the rear surface of the display panel 10. The adhesive member 80 may be disposed along an edge of the display panel 10 and an edge of the cover bottom 20. The adhesive member 80 may be formed in a shape corresponding to the edge of the display panel 10. For example, the adhesive member 80 may be configured in a frame shape corresponding to the edge of the display panel 10, but the embodiments of the present disclosure are not limited thereto. For example, the adhesive member 80 may be an adhesive foam tape, a double-sided tape, a double-sided foam tape, or a double-sided foam pad, but is not limited thereto.

Hereinafter, the heat dissipation member will be described in detail with reference to FIGS. 3 to 6.

FIG. 3 is a plan view of a rear surface of a display apparatus according to an embodiment of the present disclosure.

Referring to FIG. 3, a portion of the heat dissipation member 60 may overlap the printed circuit board 40.

The heat dissipation member 60 may be disposed in the form of a long tube over the first region A and the second region B of the display apparatus 100. For example, the heat dissipation member 60 may have one configuration in which a first portion 60a, a second portion 60b, and a third portion 60c connected to each other are integrated, but is not limited thereto. The first portion 60a, the second portion 60b, and the third portion 60c may be connected by a single tube without being broken.

Since the heat dissipation member 60 is disposed to overlap the printed circuit board 40, which is the main cause of heat generation when the display apparatus 100 is driven, the high-temperature heat generated in the first region A may be moved from the display apparatus 100 toward the second region B, which has a relatively low temperature. The low-temperature heat of the second region B, which has a relatively low temperature, may be moved to the high-temperature first region A due to high-temperature heat moved from the first region A. Accordingly, the temperature deviation of the display apparatus 100 may be reduced. In FIG. 3, the heat dissipation member 60 is disposed in a ‘U’ shape, but the embodiments of the present disclosure are not limited thereto. For example, the heat dissipation member 60 may be variously modified depending on the temperature distribution of the display apparatus 100.

The inside of the heat dissipation member 60 is in a vacuum, and a working fluid may be injected into the heat dissipation member in the vacuum. The working fluid may have a characteristic of easily changing the phase into vapor under a low pressure condition. The working fluid may be water, a Freon-based refrigerant, ammonia, acetone, methanol, or ethanol, but the embodiments of the present disclosure are not limited thereto.

The working fluid in the heat dissipation member 60 may be easily evaporated because the pressure is very low in a vacuum. For example, when heat is generated in the printed circuit board 40, the working fluid inside the heat dissipation member 60 is rapidly vaporized to change the phase into vapor, and is moved to a low-temperature region of the heat dissipation member due to the pressure difference in the heat dissipation member. When the phase of the working fluid is changed into vapor, the temperature of the display apparatus 100 is decreased due to the heat of vaporization, the vapor that has moved to the low-temperature region may increase in temperature as it liquefies, resulting in resulting in a uniform temperature deviation on the front surface of the display apparatus 100. Since the heat dissipation member 60 is in a vacuum, the pressure is very low, so heat exchange may occur quickly.

The heat dissipation member 60 may include a first portion 60a, a second portion 60b, and a third portion 60c, as described above. The first portion 60a may be a portion that overlaps the printed circuit board 40, and may be a portion where heat generated from the printed circuit board 40 is in contact with or is disposed close to the printed circuit board 40. The first portion 60a may include an evaporator in which heat generated from the printed circuit board evaporates the working fluid within the heat dissipation member 60.

The second portion 60b may be a portion spaced apart from the printed circuit board at a predetermined distance, and may include a condenser in which the vaporized working fluid is moved to the second region B with a relatively low temperature to be liquefied.

The third portion 60c is between the first portion 60a and the second portion 60b, and may include a passage through which the working fluid moves the vapor vaporized by the printed circuit board 40 to the second portion 60b.

In FIG. 3, the heat dissipation member 60 is disposed in a “U” shape, but the embodiments of the present disclosure are not limited thereto. For example, the heat dissipation member 60 may be variously modified depending on the temperature distribution of the display apparatus 100.

FIG. 4 is a cross-sectional view taken along line I-I′ of FIG. 2 according to an embodiment of the present disclosure. FIG. 4 is a cross-sectional view of the display apparatus on which the printed circuit board 40 is disposed, and is an enlarged cross-sectional view of the area where the printed circuit board 40 is disposed.

According to an embodiment of the present disclosure, a heat dissipation member 60 may be disposed between the printed circuit board 40 and the display panel 10.

The heat dissipation member 60 may prevent the printed circuit board 40 and the display panel 10 from coming into direct contact, thereby preventing the temperature of a specific area of the display panel 10 from excessively rising due to the heat of the printed circuit board 40. The printed circuit board 40 may include a plurality of components, and among the plurality of components, some driving chips that generate a lot of heat may be disposed thereon. The plate bottom 30 may distribute heat generated from some driving chips of the printed circuit board 40 throughout the plate bottom 30, so that the heat is not concentrated on some areas of the display panel 10 adjacent to the driving chip, and the overall temperature deviation of the display panel is reduced.

Referring to FIG. 4, the display apparatus may further include a plate bottom 30 to further block heat generated from the printed circuit board 40.

The plate bottom 30 is disposed between the display panel 10 and the heat dissipation member 60 to increase the distance between the display panel 10 and the printed circuit board 40, so that the heat from moving to some areas of the display panel adjacent to the driving chip may be blocked.

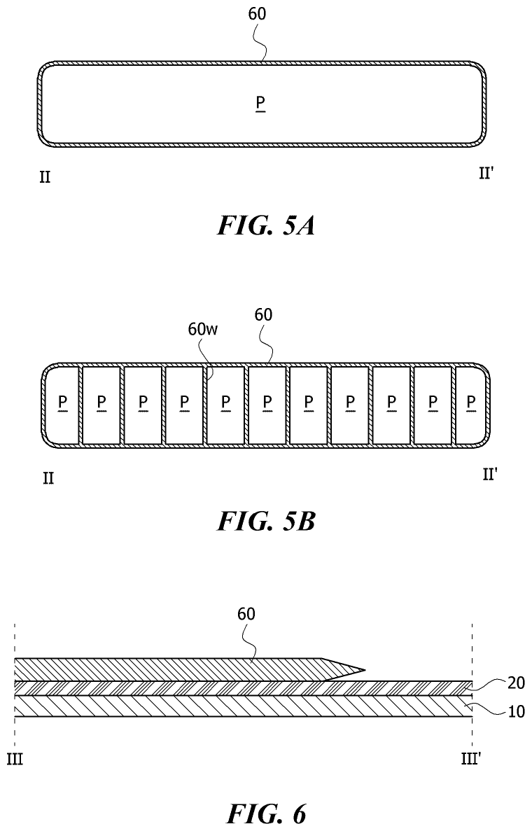

FIG. 5A is a cross-sectional view taken along line II-II′ of FIG. 2 according to an embodiment of the present disclosure.

Referring to FIG. 5A, the heat dissipation member 60 may be a heat exchange tube made of a pipe-shaped tube body, but is not limited thereto.

The heat dissipation member 60 may include a lower surface and an upper surface in order to effectively move heat generated from the printed circuit board 40. For example, the lower and upper surfaces of the heat dissipation member 60 may overlap the surface of the printed circuit board 40, and the printed circuit board 40 may completely cover the heat dissipation member 60, but is not limited thereto. The lower and upper surfaces of the heat dissipation member 60 may be longer than the side surfaces of the heat dissipation member 60.

The heat dissipation member 60 may be made of a material with high thermal conductivity. For example, the heat dissipation member 60 may be made of one of graphite, aluminum (Al), and copper (Cu), but is not limited thereto.

The inside of the heat dissipation member 60 may be an empty space P, and a working fluid may be injected into the heat dissipation member 60.

FIG. 5B is a cross-sectional view taken along line II-II′ of FIG. 2 according to another embodiment of the present disclosure.

Referring to FIG. 5B, the heat dissipation member 60 may include a plurality of partition walls 60w within the heat dissipation member 60 and may include empty spaces P divided by the plurality of partition walls 60w.

The plurality of partition walls 60w are configured in the longitudinal direction of the heat dissipation member 60, and a working fluid may be injected into each space P. Since the fluid separated by the plurality of partition walls 60w moves heat individually depending on the position of heat generated on the printed circuit board 40, it is possible to quickly disperse heat concentrated on some areas of the display apparatus 100.

FIG. 6 is a cross-sectional view taken along line III-III′ of FIG. 2 according to an embodiment of the present disclosure.

The central portion of the end of the heat dissipation member 60 may protrude further than the upper and lower ends of the heat dissipation member 60. For example, in the process of manufacturing the heat dissipation member 60, the central portion of the heat dissipation member 60 may protrude due to cutting while the metal material is extruded.

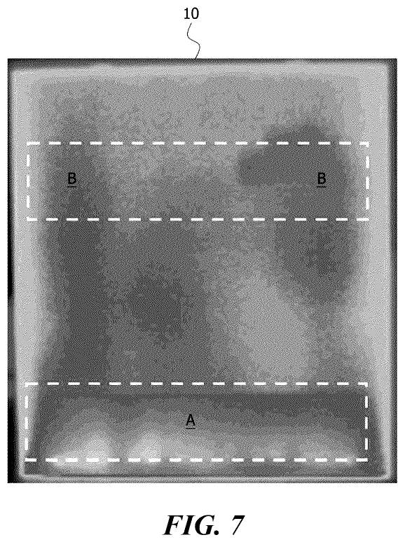

FIG. 7 is a simulation result showing a temperature of a display apparatus according to an embodiment of the present disclosure.

Referring to FIG. 7, a darker contrast area indicates a higher temperature and a lighter contrast area indicates a lower temperature. Compared to FIG. 1, it may be seen that the temperature distribution of the display apparatus 100 is uniform.

As a result of measuring the temperature of the display apparatus 100 including the heat dissipation member 60, it may be seen that the maximum temperature is measured to be about 45° C. in the first region A, which is about 10° C. lower than the display apparatus of FIG. 1, and the minimum temperature in the second region B is measured to be about 43° C., which is about 3° C. higher than the display apparatus in FIG. 1. For example, it can be seen that the temperature deviation from 15° C. in FIG. 1 is rapidly reduced to about 2° C.

Since the display apparatus according to the embodiment of the present disclosure includes a heat dissipation member, it is possible to reduce the temperature deviation depending on the position of the display apparatus, and minimize heat concentration on some areas of the display panel by diffusing heat generated from the printed circuit board throughout the display panel. In addition, the display quality may be improved by minimizing visible spots or color differences in the display panel due to the temperature deviation.

Hereinafter, other embodiments of the heat dissipation member 60 will be described in detail.

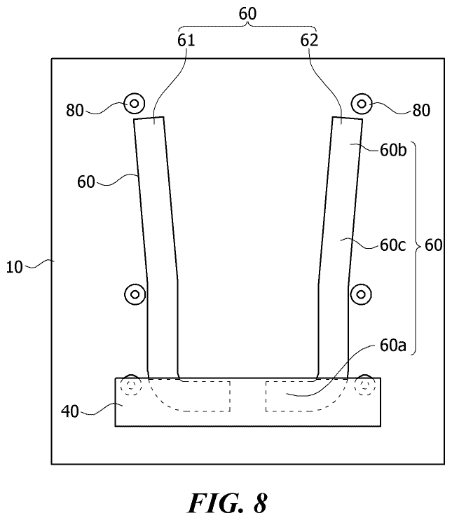

FIGS. 8 to 10 are plan views of a display apparatus including a heat dissipation member according to another embodiment of the present disclosure. FIGS. 8 to 10 are substantially the same as FIGS. 3 to 6 except for the shape of the heat dissipation member 60, and thus a repeated description thereof may be omitted or simplified.

FIG. 8 is a plan view of a display apparatus including a heat dissipation member according to another embodiment of the present disclosure.

Referring to FIG. 8, as compared with FIG. 3, the heat dissipation member 60 may have the same diameter, have an ‘L’ shape, and may include two or a plurality of heat dissipation members. For example, the heat dissipation member 60 may include a first heat dissipation member 61 and a second heat dissipation member 62. Each of the first heat dissipation member 61 and the second heat dissipation member 62 includes a first portion 60a, a second portion 60b, and a third portion 60c connected to each other, and the first portion 60a, the second portion 60b, and the third portion 60c may be connected through one tube without being broken.

The first heat dissipation member 61 and the second heat dissipation member 62 are not connected and are spaced apart from each other. For example, the first portion 60a of the first heat dissipation member 61 and the first portion 60a of the second heat dissipation member 62 are spaced apart from each other, and the spaced areas of the first heat dissipation member 61 and the second heat dissipation member 62 overlap the printed circuit board 40.

Compared to FIG. 3, the shape in which the heat dissipation member 60 is separated into two or a plurality of pieces in an ‘L’ shape means that the length of the heat dissipation member is shorter. This allows the heat to be separated and moved individually depending on the position of the heat generated on the printed circuit board 40, and quickly disperses the heat by moving the heat in one direction, for example, in one direction along the L′ shape.

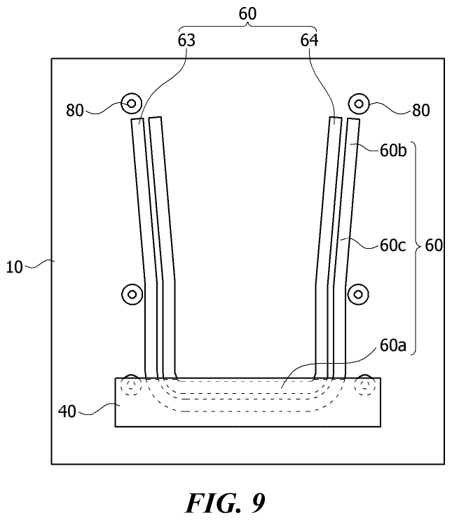

FIG. 9 is a plan view of a display apparatus including a heat dissipation member according to another embodiment of the present disclosure.

Referring to FIG. 9, the heat dissipation member 60 may include two or a plurality of ‘U’ shaped heat dissipation members with a smaller diameter compared to FIG. 3. For example, the heat dissipation member 60 may include a third heat dissipation member 63 and a fourth heat dissipation member 64. Each of the third heat dissipation member 63 and the fourth heat dissipation member 64 includes a first portion 60a, a second portion 60b, and a third portion 60c, and the first portion 60a, the second portion 60b, and the third portion 60c may be connected through one tube without being broken.

The third heat dissipation member 63 may be disposed adjacent to the fourth heat dissipation member 64. The third heat dissipation member 63 may be disposed to surround the fourth heat dissipation member 64. Accordingly, it is separated according to the position of the heat generated from the printed circuit board 40 and the heat may be individually moved.

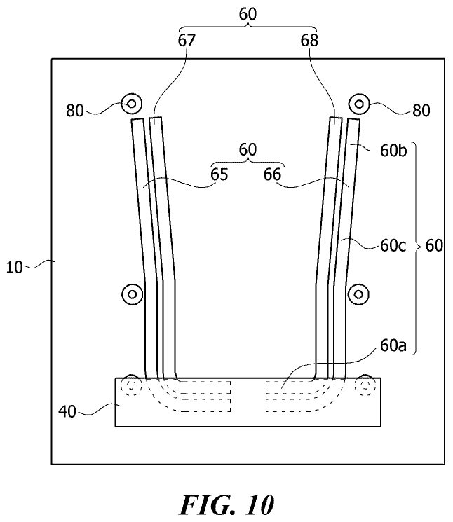

FIG. 10 is a plan view of a display apparatus including a heat dissipation member according to another embodiment of the present disclosure.

Referring to FIG. 10, as compared to FIG. 3, the heat dissipation member 60 has an “L” shape and a smaller diameter, and may include four or a plurality of heat dissipation members 60. For example, the heat dissipation member 60 may include a fifth heat dissipation member 65, a sixth heat dissipation member 66, a seventh heat dissipation member 67, and an eighth heat dissipation member 68.

Each of the fifth heat dissipation member 65, the sixth heat dissipation member 66, the seventh heat dissipation member 67, and the eighth heat dissipation member 68 includes a first portion 60a, a second portion 60b, and a third part 60c connected to each other, and the first portion 60a, the second portion 60b, and the third portion 60c may be connected through one tube without being broken.

The fifth heat dissipation member 65 may be disposed adjacent to the seventh heat dissipation member 67. The fifth heat dissipation member 65 may be disposed to surround the seventh heat dissipation member 67. The sixth heat dissipation member 66 may be disposed adjacent to the eighth heat dissipation member 68. The sixth heat dissipation member 66 may be disposed to surround the eighth heat dissipation member 68.

Hereinafter, the display panel of the present disclosure will be described in detail with reference to FIGS. 11 to 16.

FIG. 11 is a block diagram illustrating a configuration of a display panel according to an embodiment of the present disclosure.

Referring to FIG. 11, the display apparatus includes a display panel 10 in which a plurality of pixels are arranged in a display area AA, and a driving circuit for driving the pixels.

The display panel 10 may be a panel having a rectangular structure with a length in the X-axis direction, a width in the Y-axis direction, and a thickness in the Z-axis direction. The pixels include a plurality of sub-pixels SP with different colors. The driving circuit includes a data driver DD, a gate driver GD, and a timing controller TC that controls the gate driver GD and the data driver DD. The display area AA on which an input image is displayed on the display panel 10 may be a screen visible from the front surface of the display panel 10.

The input image is displayed on the subpixels SP disposed in the display area AA of the display panel 10. Each of the subpixels SP includes a light emitting element and the pixel circuit that drives the light emitting element. The light emitting element may be an inorganic material, and embodiments of the present disclosure are not limited thereto. The light emitting element may be a light emitting diode (LED) or a micro light emitting diode (micro LED), and embodiments of the present disclosure are not limited thereto.

On the display panel 10, a plurality of scan wirings SL and a plurality of data wirings DL are arranged to cross each other. Each of the subpixels SP is connected to a scan wiring SL and a data wiring DL. Power supply wirings may be connected to each of the subpixels SP. In a display panel 10, a non-display area NA may be disposed on the periphery of or around the display area AA.

The gate driver GD supplies scan signals to the scan wirings SL in response to a gate control signal provided by the timing controller TC. The gate driver GD may be disposed in the non-display area NA of the display panel 10, or may be disposed within the display area AA.

The data driver DD converts the image data received from the timing controller TC into a reference compensation voltage and outputs a data voltage in response to a data control signal provided by the timing controller TC. The data voltage output from the data driver DD is fed to the data wirings DL.

The timing controller TC aligns image data input from the outside and supplies the aligned image data to the data driver DD. The timing controller TC may generate gate control signals and data control signals based on timing signals synchronized with input image signals, for example, dot clock signals, data enable signals, and horizontal/vertical synchronization signals. The timing controller TC supplies the gate control signals to the gate driver GD and the data control signals to the data driver DD to control the timing of the operation of the gate driver GD and the data driver DD.

The non-display area NA may have link wirings and pad electrodes disposed therein to transmit signals to the subpixels SP in the display area AA. Furthermore, one or more of a gate driver IC in which circuits for the gate driver GD are integrated and a data driver IC in which circuits for the data driver DD are integrated may be disposed in the non-display area NA. The non-display area NA may be located on the rear surface of the display panel 10, for example, on the rear surface where there are no subpixels SP, or it may be minimized to the extent that it is invisible when an image is displayed on the display panel 10.

The drivers such as the gate driver GD, the data driver DD, and the timing controller TC may be connected to the display panel 10 in a variety of ways. For example, the gate driver GD may be disposed in a gate in panel (GIP) fashion in the non-display area NA, or in a gate in active area (GIA) fashion between subpixels SP in the display area AA, and embodiments of the present disclosure are not limited thereto. For example, the data driver DD and the timing controller TC may be formed on separate flexible films and printed circuit boards (hereinafter referred to as “PCB”), and the data driver DD and the timing controller TC may be electrically connected to the display panel 10 by bonding the flexible films and the PCBs to pad electrodes formed on the non-display area NA of the display panel 10.

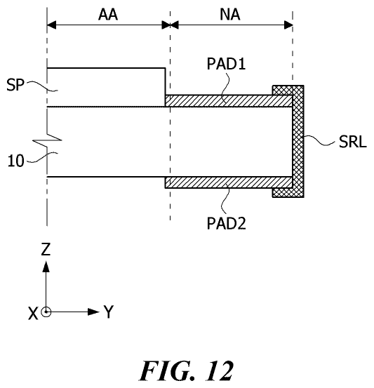

A side wiring for connecting the signal wirings on the front surface of the display panel 10 to the pad electrodes in the back surface of the display panel 10 may be formed on the outermost side surface of the display panel 10. Such a method of electrical connection between the front surface and the back surface of the display panel 10 via the side wiring may maximally minimize the non-display area NA visible on the front surface of the display panel 10. In FIG. 12, “SRL” denotes this side wiring. When the gate driver GD, the data driver DD, and the timing controller TC are connected to the display panel 10 in the above manner, a screen without a bezel may be substantially realized.

FIG. 12 is a cross-sectional view illustrating a printed circuit board disposed at the outermost portion of the display panel and a side wiring according to an embodiment of the present disclosure.

Referring to FIG. 12, a plurality of pad electrodes are disposed in the non-display area NA of the display panel 10 to transmit various signals to the subpixels SP. For example, a first pad electrode PAD1, which transmits signals to the subpixels SP, may be disposed in the non-display area NA located at the front surface of the display panel 10. A second pad electrode PAD2, which is electrically connected to circuit components such as the flexible films and the PCBs, may be disposed in the non-display area NA at the back surface of the display panel 10. Only the pad area in which the first pad electrode PAD1 is located is arranged in the non-display area NA located at the front outermost portion of the display panel 10 in which an image is displayed, thereby minimizing the size of the non-display area.

Various signal wirings associated with the subpixels SP, such as the scan wiring SL or the data wiring DL, may extend into the non-display area NA and be electrically connected to the first pad electrode PAD1.

The display panel 10 may include the side wiring SRL disposed on the outermost side surface of the display panel 10. The side wiring SRL may electrically connect the first pad electrode PAD1 disposed on the front outermost portion of the display panel 10 and the second pad electrode PAD2 disposed on the back outermost portion of the display panel 10 while traversing the side surface of the display panel 10. The signals output from the circuit components disposed at the back surface of the display panel 10 may be transmitted to the subpixels SP within the display area AA via the second pad electrode PAD2, the side wiring SRL, and the first pad electrode PAD1. Accordingly, a signal transmission path traversing the front, side, and rear surfaces may be formed at the outermost portion of the display panel 10, thereby minimizing the area of the non-display area NA on the front surface of the display panel 10.

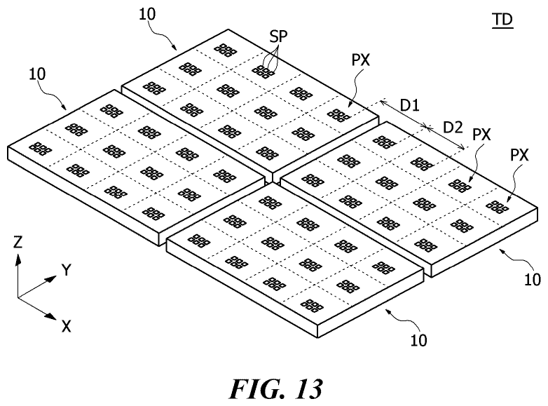

FIG. 13 is a perspective view representing a tiled display apparatus according to an embodiment of the present disclosure.

As illustrated in FIG. 13, a plurality of display modules may be combined on a plane to be implemented as a large-screen tiled display apparatus.

Referring to FIG. 13, a large-screen tiled display apparatus TD may include a plurality of display modules disposed in an X-Y plane. Each of the plurality of display modules may include a single sheet of a display panel 10, a driving circuit for the display panel 10, and circuit components and members coupled to the rear surface of the display panel 10 as described in FIGS. 2 to 11.

Each of the plurality of display modules may include the display panel 10 on which the input image is reproduced. When the non-display area NA at the front outermost portion of each display panel 10 is minimized, the large-screen image with no visible seams between neighboring display panels 10 may be reproduced.

The display panels 10 may be assembled in a plane such that the spacing D1 between the outermost pixel PX of one display panel 10 and the outermost pixel PX of another display panel 10 adjacent to that display panel 10 is substantially the same as the spacing D1 between neighboring pixels PX within the display area of the display panel 10. Accordingly, the spacing D1 between the neighboring outermost pixels PX of the display panel 10 throughout the large-screen display area of the tiled display apparatus TD becomes the same as the spacing D2 between the neighboring pixels PX within the display area of the display panel 10, and thus the seam area is not visible.

In the tiled display apparatus TD, multiple display modules may share one timing controller TC. A host system may be connected to a plurality of timing controllers TC, may transmit to the timing controllers TC image signals to be reproduced on all of the display panels 10 implementing the large-screen of the tiled display apparatus TD, and may synchronize the timing controllers TC.

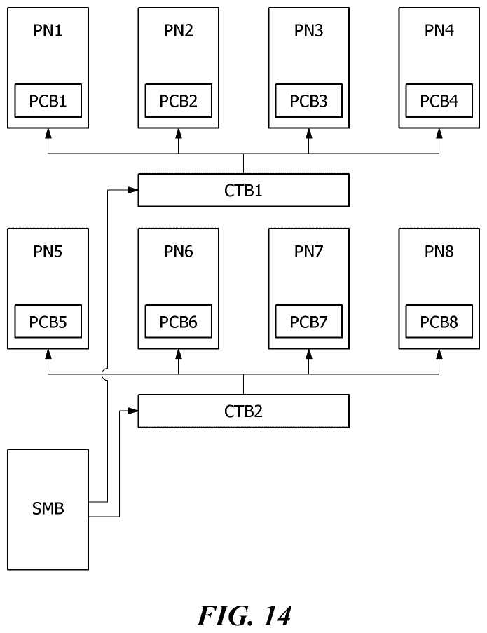

FIG. 14 is a block diagram representing control boards connected to a plurality of printed circuit boards and a system board connected to the control boards.

Referring to FIG. 14, each of the display modules may include a single sheet of a display panel 10 and one PCB. A system board SMB is connected to M (M is an integer greater than or equal to 2) control boards CTB1, CTB2. Each of the control boards CTB1, CTB2 is connected to N (N is an integer greater than M) PCBs.

According to an embodiment of the present disclosure, the display modules may include the first to fourth display modules. The first to fourth display modules may include first to fourth display panels PN1, PN2, PN3, and PN4. A first control board CTB1 may be connected to the PCBs of a first to fourth display modules PCB1 to PCB4 via flexible films or cables.

According to an embodiment of the present disclosure, the display modules may include fifth to eighth display modules. The fifth to eighth display modules may include fifth through eighth display panels PN5, PN6, PN7, and PN8. A second control board CTB2 may be connected to the PCBs of a fifth to eighth display modules PCB5 through PCB8 via flexible films or cables. The system board SMB may be connected to the first and second control boards CTB1, CTB2 via flexible films or cables.

The system board SMB may be a main board of the host system. The system board SMB includes a user interface port to receive user input, an external interface port connected to external devices, a communication module to delay various communication protocols, a processor to process multi-media signals, a central processing unit (CPU), and a main power supply, and the embodiment of the present disclosure are not limited thereto.

Referring to FIG. 11 together, the system board SMB sends an input image signal and a timing signal to the control boards CTB1, TB2. The timing controllers TC mounted on the control boards CTB1, CTB2 transmits the received image signal to the data driver DD and controls the data driver DD and the gate driver GD based on the timing signal. The driving circuits DD, GD for the N display modules write image data to the corresponding display panels 10 under the control of one timing controller TC.

FIG. 15 is a plan view illustrating a planar structure of a display panel according to an embodiment of the present disclosure.

Referring to FIG. 11 and FIG. 15, a display panel 10 includes a substrate SUBS on which a pixel array and a circuit for a gate driver GD are disposed.

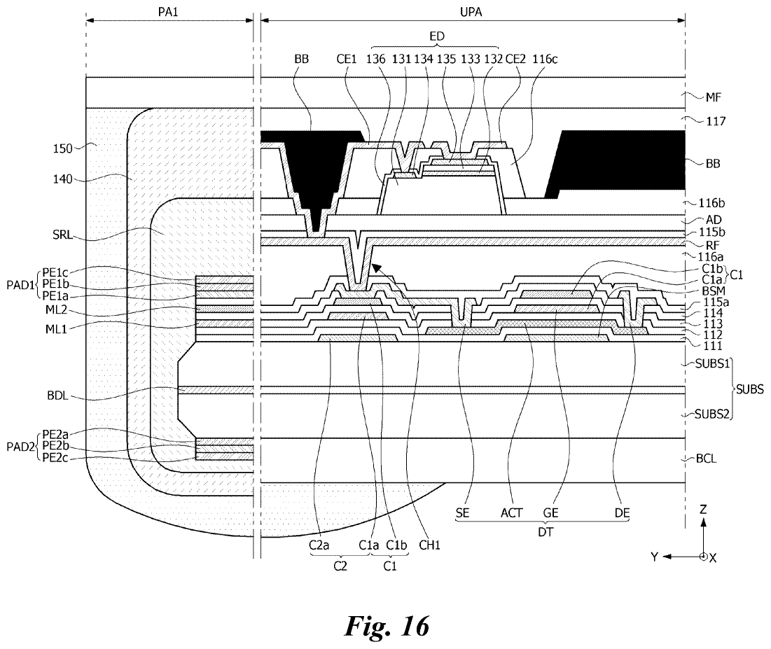

The substrate SUBS may be an insulating substrate that supports components disposed on a display apparatus. The substrate SUBS may have a stacked structure of first and second substrates SUBS1, SUBS2, as shown in FIG. 16. Each of the first and second substrates SUBS1, SUBS2 may be fabricated as a glass, polymer resin, or plastic substrate. Each of the first and second substrates SUBS1, SUBS2 may be made as a flexible substrate that has flexibility, but is not limited thereto.

On one surface (or front surface) of the substrate SUBS, a display area AA may include a plurality of pixel areas UPA, a plurality of gate driving areas GA, and a plurality of pad areas PA1, PA2. One or more pixels PX may be disposed in each of the pixel areas UPA. The pixel areas UPA may be arranged along a plurality of row lines and a plurality of column lines. Each of the pixels PX include a plurality of subpixels SP with different colors. Each of the subpixels SP may emit light independently, including light emitting elements and pixel circuit. The subpixels SP may include, but are not limited to, red subpixels, blue subpixels, and green subpixels.

The plurality of gate driving areas GA includes circuits for gate drivers GD. The gate driving areas GA may be formed along a row direction and/or a column direction between the plurality of pixel areas UPA. A gate driver GD formed in a gate driving area GA may provide a scan signal to a plurality of scan wrings SL.

A first pad area PA1 includes a plurality of first pad electrodes PAD1 disposed on the front outermost portion of one side (or upper side) of the display panel 10. The first pad electrodes PAD1 may transmit various signals to various wirings extending in the column direction from the display area AA. The first pad electrodes PAD1 include data pads DP connected to the data wiring DL to deliver the data voltage from the data driver DD to the data wiring DL, and gate pads GP connected to the gate driver GD to transmit clock signals, start signals, gate low voltage, and gate high voltage to the gate driver GD for driving the gate driver GD. The clock signals, start signals, gate low voltages, and gate high voltages for driving the gate driver GD may be generated from the timing controller TC and applied to the gate pads GP through a level shifter and a PCB. The first pad electrodes PAD1 may include a plurality of power wirings to which a direct current voltage (or a constant voltage) is applied.

A second pad area PA2 includes a plurality of first pad electrodes PAD1 disposed on the front outermost portion of the other side (or lower side) of the display panel 10. The second pad area PA2 may include a plurality of low-potential power supply pads VP2.

A power supply circuit may be disposed on the PCB or the control boards CTB1, CTB2 disposed on the rear surface of the display panel 10. The power supply circuit may be a DC-DC converter that converts a direct current input voltage from the main power source to a direct current voltage suitable for driving the display panel 10. The direct current voltage to be applied to the power supply wirings may be output from the power supply circuit, and may be applied to the pads VP1 and VP2 connected to the power supply wirings through the PCB.

The power supply pads connected to the power supply wirings may include a plurality of high-potential power supply pads VP1 and a plurality of low-potential power supply pads VP2. The plurality of high-potential power supply pads VP1 are disposed on the first pad area PA1 and may transfer high-potential power supply voltages to the high-potential power supply wiring VL1. The plurality of low-potential power supply pads VP2 are disposed on the second pad area PA2 and may transfer low-potential power supply voltages to the low-potential power supply wiring VL2. For example, the plurality of high-potential power supply pads VP1 may be first power supply pads, and embodiments of the present disclosure are not limited thereto. For example, the plurality of low-potential power supply pads VP2 may be second power supply pads, and embodiments of the present disclosure are not limited thereto.

The data pads DP, which are connected one-to-one to the data wirings DL, may have a relatively narrow width, while the power pads VP1, VP2 and the gate pads GP may have a relatively wide width, and embodiments of the present disclosure are not limited thereto. The low-potential power supply pads VP2 may have a wider width compared to the high-potential power supply pads VP2, and embodiments of the present disclosure are not limited thereto. The widths of the pads DP, GP, VP1, and VP2 are not limited to those shown in FIG. 15.

In order to minimize the outermost non-display area NA of the display panel 10, the pixel array, the wirings, and the pads are formed on the front surface of the substrate of the display panel 10, and then the outermost portion of the substrate may be cut and removed along a scribe line indicated by a dotted line, thereby providing the substrate with the removed portion OSUBS outside of the scribe line. After the scribing process, the rough edge of the outermost side surface of the substrate SUBS may be ground or laser trimmed. After grinding or laser trimming, the reduced size pad electrodes PAD1, PAD2 are left on the front outermost portion of the substrate SUBS.

The data wirings DL may extend in the column direction Y on the first substrate SUBS1 and overlap the pixel areas UPA. The data wirings DL supply the data voltages to the respective pixel circuits of the subpixels SP. The scan wirings SL may extend in the row direction X on the substrate SUBS of the display panel 10 and overlap the pixel areas UPA and the gate driving areas GA. The scan wirings SL may supply the scan signals from the gate driver GD across the pixel areas UPA and the gate driving areas GA to the respective pixel circuits of the subpixels SP.

The high-potential power supply wirings VL1 extend in the column direction Y, and at least one of the high-potential power supply wirings VL1 is connected in a mesh structure to auxiliary high-potential power wirings AVL1 extending in the row direction X. The auxiliary high-potential power supply wirings AVL1 are connected to the subpixels SP arranged in the row direction X. Therefore, the high-potential power supply voltages applied to the high-potential power supply wirings VL1 may be delivered to the subpixels SP via the auxiliary high-potential power supply wirings AVL1.

The low-potential power supply wirings VL2 extend in the column direction Y, and at least one of the low-potential power supply wirings VL2 is connected in a mesh structure to auxiliary low-potential power supply wirings AVL2 extending in the row direction X. The auxiliary low-potential power supply wirings AVL2 are connected to the subpixels SP arranged in the row direction X. Therefore, the subpixels SP are connected to the auxiliary high-potential power supply wirings AVL1 to which the low-potential power supply voltage is applied.

The mesh structure of the power supply wirings may allow the resistance of the power supply wirings to be reduced, which may improve the voltage drop of the high-potential power supply voltage and the deviation of the power supply voltage within the display area AA.

A plurality of gate driving wirings GVL extending in the row direction is disposed on the first substrate SUBS1 of the display panel 10. The plurality of gate driving wirings GVL carries signals necessary to drive the gate drivers GD disposed in the gate driving area GA, such as clock signals, start signals, gate high voltages, gate low voltages, etc.

The substrate SUBS1 of the display panel 10 may include one or more alignment keys AK1, AK2 arranged between the pixel areas UPA. The alignment keys AK1, AK2 may be used for alignment in the manufacturing process of the display panel 10. A first alignment key AK1 may be disposed in the gate driving area GA. The first alignment key AK1 may be used to check the aligned position of each of the light emitting elements. The first alignment key AK1 may be formed in a cross pattern, but is not limited thereto. A second alignment key AK2 may overlap the high-potential power supply wiring VL1. The high-potential power supply wiring VL1 may include a hole formed in a position overlapping the second alignment key AK2, so that the second alignment key AK2 and the high-potential power supply wiring VL1 may be distinguished. The second alignment key AK2 may be used to align the display panel 10 with a donor substrate. The donor substrate is an intermediate medium for mounting light emitting elements on the substrate SUBS of the display panel 10. A plurality of light emitting elements fabricated on a semiconductor wafer may be attached to and transferred to the donor substrate, and the light emitting elements attached to the donor substrate may be transferred onto the substrate SUBS. The second alignment key AK2 may be formed in a circular or ring pattern, but is not limited thereto.

FIG. 16 is a plan view illustrating a planar structure of a display panel according to an embodiment of the present disclosure.

Referring to FIG. 16, a pixel circuit for driving a light emitting device ED is disposed in each of a plurality of subpixels SP on a first substrate SUBS1. The pixel circuit may include a plurality of thin film transistors and one or more capacitors. In FIG. 6, a driving transistor DT, a first capacitor C1, and a second capacitor C2 are illustrated in the pixel circuit for case of description, but other circuit elements may also be included without limitation.

A first metal layer may be disposed on a first substrate SUBS1. For example, the first metal layer may be formed by patterning a first metal layer. The first metal layer may include a light shielding layer BSM. The light shielding layer BSM may block light from entering an active layer ACT of the driving transistor DT to minimize leakage current. The light shielding layer BSM may be formed of an opaque conductive material, e.g., a metal such as copper (Cu), aluminum (Al), molybdenum (Mo), nickel (Ni), titanium (Ti), chromium (Cr), an alloy of these metals, or a multilayer of metal layers, and embodiments of the present disclosure are not limited thereto.

A buffer layer 111 may be disposed on the light shielding layer BSM. The buffer layer 111 may block the penetration of moisture or impurities through the first substrate SUBS1. The first metal layer may be formed of silicon oxide (SiOx), silicon nitride (SiNx), or a multilayer of insulating layers.

The active layer ACT and the driving transistor DT including a gate electrode GE, a source electrode SE, and a drain electrode DE may be disposed on the buffer layer 111.

The active layer ACT may be made of a semiconductor material such as, but not limited to, an oxide semiconductor, amorphous silicon, or polysilicon. The gate insulating layer 112 electrically isolates the active layer ACT and the gate electrode GE of the driving transistor DT. The gate insulating layer 112 may be formed of silicon oxide (SiOx), silicon nitride (SiNx), or a multilayer of insulating layers, and embodiments of the present disclosure are not limited thereto.

A second metal layer may be disposed on the gate insulating layer 112. For example, the second metal layer may be formed by patterning a second metal layer. The second metal layer may include the gate electrode GE of the driving transistor DT. The second metal layer may be formed of copper (Cu), aluminum (Al), molybdenum (Mo), nickel (Ni), titanium (Ti), chromium (Cr), or a multilayer of metal layers, and embodiments of the present disclosure are not limited thereto.

A first interlayer insulating layer 113 and a second interlayer insulating layer 114 are disposed on the gate electrode GE. The first interlayer insulating layer 113 and the second interlayer insulating layer 114 may have contact holes formed therein for connecting the source electrode SE and the drain electrode DE of the driving transistor DD to the active layer ACT, respectively. Each of the first interlayer insulating layer 113 and the second interlayer insulating layer 114 may be formed of silicon oxide (SiOx), silicon nitride (SiNx), or a multilayer of insulation layers, and embodiments of the present disclosure are not limited thereto.

A third metal layer may be disposed on the second interlayer insulating layer 114. For example, the third metal layer may be formed by patterning a third metal layer. The third metal layer may include the source electrode SE and the drain electrode DE overlapping the active layer ACT and connected to the active layer ACT through the contact holes that penetrate the interlayer insulating layers 113, 114. The source electrode SE may be connected to the capacitors C1, C2 and the first electrode 134 of the light emitting element ED. The third metal layer may be formed of copper (Cu), aluminum (Al), molybdenum (Mo), nickel (Ni), titanium (Ti), chromium (Cr), or a multilayer of metal layers, and embodiments of the present disclosure are not limited thereto.

The first capacitor C1 includes a first capacitor electrode C1a and a second capacitor electrode C1b. The first capacitor electrode C1a may be formed as the second metal layer disposed on the gate insulating layer 112. The second capacitor electrode C1b may be formed as a fourth metal layer disposed on the first interlayer insulating layer 113 and overlap the first capacitor electrode C1a with the first interlayer insulating layer 113 interposed therebetween. The second capacitor electrode C1b may be connected to the source electrode SE of the driving transistor DT. The fourth metal layer may be formed of copper (Cu), aluminum (Al), molybdenum (Mo), nickel (Ni), titanium (Ti), chromium (Cr), or a multilayer of metal layers, and embodiments of the present disclosure are not limited thereto.

The second capacitor C2 includes a third capacitor electrode C2a overlapping the first capacitor electrode C1a with the insulating layers 111, 112 interposed therebetween. The third capacitor electrode C2a may be formed as the first metal layer disposed on the first substrate SUBS1.

The second capacitor C2 is electrically connected between the source electrode SE of the driving transistor DT and the light emitting element ED to increase the capacitance of the light emitting element ED, which may increase the brightness when the light-emitting element ED emits light.

A first passivation layer 115a may cover the third metal layer and the second interlayer insulating layer 114 so as to cover the third metal layer. The first passivation layer 115a may be formed of silicon oxide (SiOx), silicon nitride (SiNx), or a multilayer of insulating layers, and embodiments of the present disclosure are not limited thereto. The first passivation layer 115a may be a first protective layer or a first insulating layer, and embodiments of the present disclosure are not limited thereto.

A first planarization layer 116a is disposed on the first passivation layer 115a. The first planarization layer 116a may be formed of silicon oxide (SiOx), silicon nitride (SiNx), or a multilayer of insulating layers, and embodiments of the present disclosure are not limited thereto. The first planarization layer 116a may cover the first passivation layer 115a to planarize the surface on which the light emitting element is disposed. The first planarization layer 116a may be a single layer or a multilayer of insulating layers made of benzocyclobutene or acryl-based organic material, and embodiments of the present disclosure are not limited thereto.

A fifth metal layer may be disposed on the first planarization layer 116a. For example, the third metal layer may be formed by patterning a third metal layer. The fifth metal layer may include a light reflective layer RF. The reflective layer RF may reflect light from the light emitting element ED toward the front of the display panel 10 to increase light efficiency, and may be used as an electrode to connect the light emitting element ED to the pixel circuit or the power supply wirings. The reflective layer RF may be electrically connected to the source electrode SE of the driving transistor DT and the first capacitor C1 via a contact hole CHI penetrating the first planarization layer 116a and the first passivation layer 115a. Further, the reflective layer RF may be electrically connected to a first electrode 134 of the light emitting element ED via a first connection electrode CE1, or may be electrically connected with a second electrode 135 of the light emitting element ED via the high-potential power supply wiring VL1. The fifth metal layer may be formed of a transparent electrode material such as silver (Ag), aluminum (Al), molybdenum (Mo), titanium (Ti), indium tin oxide (ITO), or a multilayer of metal layers, and embodiments of the present disclosure are not limited thereto.

A second passivation layer 115b may cover the fifth metal layer and the first planarization layer 116a. The second passivation layer 115b may be formed of silicon oxide (SiOx), silicon nitride (SiNx), or a multilayer of insulating layers, and embodiments of the present disclosure are not limited thereto.

An adhesive layer AD may be disposed on the second passivation layer 115b to secure the light emitting element ED. The adhesive layer AD may be formed of a photocurable resin that can be cured by light, and embodiments of the present disclosure are not limited thereto. The adhesive layer AD may be formed of, but is not limited to, an acrylic-based material containing a photosensitive agent. The adhesion layer AD may be formed on the front surface of the first substrate SUBS1 except for the pad areas PA1, PA2 in which the first pad electrode PAD1 is to be disposed, and embodiments of the present disclosure are not limited thereto.

A light emitting element ED of each of the sub-pixels SP may be disposed on the adhesive layer AD. Light emitting elements ED may emit light by current from the driving transistor DT. The light emitting elements ED may include red light emitting elements ED, green light emitting elements ED, and blue light emitting elements ED. The light emitting elements may be a light emitting diode (LED) or a micro light emitting diode, and embodiments of the present disclosure are not limited thereto.

Each of the light emitting elements ED includes a first semiconductor layer 131, a light emitting layer 132, a second semiconductor layer 133, the first electrode 134, and the second electrode 135.

The first semiconductor layer 131 is disposed on the adhesive layer AD, and the second semiconductor layer 133 is disposed on the first semiconductor layer 131. The first semiconductor layer 131 and the second semiconductor layer 133 may be formed as semiconductor patterns obtained by doping the conductor material with n-type and p-type impurities. For example, each of the first semiconductor layer 131 and the second semiconductor layer 133 may be a layer in which an n-type or p-type impurities are doped into a material such as gallium nitride (GaN), indium aluminum phosphide (InAlP), gallium arsenide (GaAs), or the like, and embodiments of the present disclosure are not limited thereto. For example, the p-type impurities may be magnesium (Mg), zinc (Zn), or beryllium (Be), and the n-type impurities may be silicon (Si), germanium (Ge), or tin (Sn), but are not limited thereto.

A light emitting layer 132 is disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may be made of a single layer or multi-quantum Well (MQW) structure, and may be formed, for example, of indium gallium nitride (InGaN) or gallium nitride (GaN), and embodiments of the present disclosure are not limited thereto.

A first electrode 134 is disposed on the first semiconductor layer 131. The first electrode 134 electrically connects the driving transistor DT and the first semiconductor layer 131. The first semiconductor layer 131 may be formed as a semiconductor layer doped with n-type impurities, and embodiments of the present disclosure are not limited thereto. The first electrode 134 may be disposed on the first semiconductor layer 131 and may be electrically connected to the driving transistor DT and capacitors C1, C2 via the reflective layer RF. For example, the first electrode 134 may be a cathode electrode of the light emitting element ED. The first electrode 134 may be disposed on an upper surface of the first semiconductor layer 131. The first electrode 134 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, and embodiments of the present disclosure are not limited thereto.

A second electrode 135 is disposed on the second semiconductor layer 133. The second electrode 135 electrically connects the high-potential power supply wiring VL1 and the second semiconductor layer 133. The second semiconductor layer 133 may be formed as a semiconductor layer doped with p-type impurities, and embodiments of the present disclosure are not limited thereto. The second electrode 135 may be a cathode electrode of the light emitting element ED. The second electrode 135 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, and embodiments of the present disclosure are not limited thereto.

The light-emitting element ED may include a sealing layer 136. The sealing layer 136 may cover the semiconductor layers 131, 133 and the first and second electrodes 134, 135 to protect the light emitting element ED. The sealing layer 136 and a third planarization layer 116c include contact holes exposing the first electrode 134 and the second electrode 135. The first connection electrode CE1 is connected to the reflective layer RE via a first contact hole penetrating the sealing layer 136 and the third planarization layer 116c. A second connection electrode CE2 is connected to the second electrode 135 via a second contact hole penetrating the sealing layer 136 and the third planarization layer 116c. A portion of a lateral surface of the first semiconductor layer 131 may be exposed without the sealing layer 136.

The second planarization layer 116b and the third planarization layer 116c may cover the adhesive layer AD and the light emitting element ED. The second planarization layer 116b is in contact with the lateral lower end of the light emitting element ED to secure the light emitting element ED. The third planarization layer 116c covers the light emitting element ED over the second planarization layer 116b. The third planarization layer 116c includes contact holes exposing the first electrode 134 and second electrode 135 of the light emitting element ED. The second planarization layer 116b and the third planarization layer 116c may be formed of a single layer or a multilayer of organic insulating materials, for example, photoresists or acryl-based organic materials, and embodiments of the present disclosure are not limited thereto.

A sixth metal layer may be disposed on the third planarization layer 116c. The sixth metal layer may be constructed by patterning. The sixth metal layer includes the first connection electrode CE1 and the second connection electrode CE2. The first connection electrode CE1 may electrically connect the first electrode 134 of the light emitting element ED and the reflective layer RF. The first connection electrode CE1 may be connected to the first electrode 134 of the light emitting element ED via a contact hole penetrating the insulating layers 116c and 136, and may be connected to the reflective layer RF via a contact hole penetrating the insulating layers 115b, AD, 116b, and 116.

The second connection electrode CE2 is connected to the second electrode 135 of the light emitting device ED via a contact hole penetrating the insulating layers 116c and 136. The second connection electrode CE2 may be connected to the low-potential power wiring VL2.

A bank BB may be disposed on the second planarization layer 116b. The bank BB may be disposed to be spaced apart from the light emitting element ED at regular intervals. The bank BB may cover a portion of the first connection electrode CE1 within a contact hole penetrating the insulating layers 116b, 116c. The bank BB may prevent optical crosstalk between subpixels SP, thereby reducing or decreasing color mixing between subpixels SP. For example, the bank BB may be formed of black resin, but is not limited thereto.

A first protective layer 117 may cover the sixth metal layers CE1, CE2, the bank BB, and the second planarization layer 116b, and the third planarization layer 116c. The first protective 117 may be formed of a single layer or a multilayer of light-transmitting epoxy, silicon oxide (SiOx), silicon nitride (SiNx), or a multilayer of insulating layers, and embodiments of the present disclosure are not limited thereto.

Each of the first pad electrodes PAD1 disposed in the pad areas PA1, PA2 of the first substrate SUBS1 may have a multilayer structure of metal layers, and embodiments of the present disclosure are not limited thereto. For example, each of the first pad electrodes PAD1 may include a first pad metal layer PE1a, a second pad metal layer PE1b, and a third pad metal layer PE1c formed on the front outermost portion of the first substrate SUBS1, and embodiments of the present disclosure are not limited thereto.

The third metal layer disposed on the second interlayer insulating layer 114 may further include the first pad metal layer PE1a. The first pad metal layer PE1a may be formed of the same material as the source electrode SE and the drain electrode DE of the driving transistor DT. For example, the first pad metal layer PE1a may be formed of copper (Cu), aluminum (Al), molybdenum (Mo), nickel (Ni), titanium (Ti), chromium (Cr), or a multilayer of metal layers, and embodiments of the present disclosure are not limited thereto.

The fifth metal layer disposed on the first planarization layer 116a may further include the second pad metal layer PE1b. The second pad metal layer PE1b may be formed of the same material as the reflective layer RF. For example, the second pad metal layer PE1b may be formed of silver (Ag), aluminum (Al), molybdenum (Mo), or a multilayer of metal layers, and embodiments of the present disclosure are not limited thereto.

A sixth metal layer disposed on the third planarization layer 116c may further include the third pad metal layer PE1c. The third pad metal layer PE1c may be formed of the same material as the first connection electrode CE1 and the second connection electrode CE2. For example, the third pad metal layer PE1c may be formed of a transparent conductive material such as indium tin oxide (ITO) or indium zinc oxide (IZO), or a multilayer of metal layers, and embodiments of the present disclosure are not limited thereto.

A first metal layer ML1 and a second metal layer ML2 and a plurality of insulating layers may be disposed under the first pad electrodes PAD1. By disposing the first metal layer ML1, the second metal layer ML2, and at least one insulating layer under the first pad electrode PAD1, the step difference of the first pad electrodes PAD1 may be adjusted. For example, the buffer layer 111, the gate insulating layer 112, the first metal layer ML1, the first interlayer insulating layer 113, and the second metal layer ML2 may be sequentially disposed between the first pad electrode PAD1 and the first substrate SUBS1, and embodiments of the present disclosure are not limited thereto. The second metal layer disposed on the gate insulating layer 112 may include the first metal layer ML1. The fourth metal layer disposed on the first interlayer insulating layer 113 may include the second metal layer ML2. The plurality of the insulating layers and the metal layers ML2, ML3 under the first pad electrodes PAD1 are not limited to those in FIG. 16.

A second substrate SUBS2 may be disposed on the rear surface of the first substrate SUBS1. A bonding layer BDL is disposed between the first substrate SUBS1 and the second substrate SUBS2. The bonding layer BDL is cured by different curing methods to bond the first substrate SUBS1 and the second substrate SUBS2. The bonding layer BDL may be disposed in only a portion of the area between the first substrate SUBS1 and the second substrate SUBS2, or it may be disposed in the entire area. The first substrate SUBS1 and the second substrate SUBS2 may be scribed and ground simultaneously so that the lateral surfaces of the first substrate SUBS1 and the second substrate SUBS2 do not have a step difference.

A plurality of second pad electrodes PAD2 may be disposed on the rear outermost portion of the second substrate SUBS2. The second pad electrodes PAD2 are electrically connected to the side wirings SRL and the first pad electrode PAD1 to transmit signals from circuit components disposed on the rear surface of the second substrate SUBS2 to the subpixels SP disposed on the upper surface of the first substrate SUBS1.

Each of the second pad electrodes PAD2 may have a multilayer structure of metal layers. For example, each of the second pad electrodes PAD2 may include a first pad metal layer PE2a, a second pad metal layer PE2b, and a third pad metal layer PE2c stacked on the rear outermost portion of the second substrate SUBS2, and embodiments of the present disclosure are not limited thereto. Each of the first and second pad metal layers PE2a, PE2b may be formed of copper (Cu), aluminum (Al), molybdenum (Mo), nickel (Ni), titanium (Ti), chromium (Cr), or a multilayer of metal layers, and embodiments of the present disclosure are not limited thereto. The third pad metal layer PE2c may be formed of a transparent conductive material such as indium tin oxide (ITO) or indium zinc oxide (IZO), and embodiments of the present disclosure are not limited thereto.

A second protective layer BCL may be disposed on the rear surface of the second substrate SUBS2. The second protective layer BCL may cover one or more wirings except for the second pad electrodes PAD2 on the back surface of the second substrate SUBS2. The second protective layer BCL may be made of an organic insulating material, for example, a benzocyclobutene or acryl-based organic insulating material, and embodiments of the present disclosure are not limited thereto.

Circuit components such as a plurality of flexible films and PCBs may be disposed on the rear surface of the second substrate SUBS2. The output terminals of the flexible film are electrically connected to the second pad electrode PAD2, and the input terminals of the flexible film are electrically connected to the output terminals of the PCB. Accordingly, a signal or voltage output from a PCB may be transmitted to the subpixels SP disposed on the front surface of the first substrate SUBS1 via the flexible film, the second pad electrode PAD2, the side wiring SRL, the plurality of first pad electrodes PAD1, and the wiring connected to the first pad electrode PAD1.

The side wirings SRL electrically connect the first pad electrodes PAD1 and the second pad electrodes PAD2 across the side surfaces of the first substrate SUBS1 and the second substrate SUBS2. The side wirings SRL may be formed on the side surface of the substrates SUBS1, SUBS2 by a pad printing method using conductive inks, for example, the conductive inks including silver (Ag), copper (Cu), molybdenum (Mo), and chromium (Cr). The material and method of formation of the side wirings SRL are not limited thereto.

A side insulating layer 140 may cover the side wirings SRL formed on at least one of the outermost front, side, and rear surfaces of the substrates SUBS1 and SUBS2 bonded together. If the side wirings are metal, external light may be reflected from the side wirings or light emitted by the emitting device ED may be reflected from the side wirings and be visible to the user. In order to improve image deterioration due to such reflected light, the side insulating layer 140 may include a black material that absorbs external light. For example, the side insulating layer 140 may be formed on the outermost portion of the substrates SUBS1, SUBS2 with black ink that can be applied by a printing method, and embodiments of the present disclosure are not limited thereto.

According to the embodiments of the present disclosure, the display panel may further include a seal 150 covering the side insulation layer 140. A seal 150 may cover the side insulating layer 140 so that it is possible to protect the display panel 10 from external shock, moisture, oxygen, etc. For example, the seal 150 may be made of an insulating material such as polyimide, poly urethane, epoxy, acryl-based insulating material, or the like, and embodiments of the present disclosure are not limited thereto.

A functional film MF may cover the front surface of the first display panel 10. For example, a functional film MF may cover the front surface of the first display panel 10. The functional film MF may include one or more of a variety of functional films, such as an anti-scattering film, an anti-glare film, an anti-reflective film, a low-reflective film, an Oled transmittance controllable film for a luminance enhancement, a color difference compensation film, a polarizing plate, and the like. The anti-scattering film prevents substrate fragments or particles from scattering when the display panel 10 is damaged. The functional film MF may be cut and removed together with the outer portion of the seal 150 along a cut line that overlaps with the seal 150 after the seal 150 has been bonded to the front surface of the first substrate SUBS1. Accordingly, the exposed side surfaces of the functional film MF and the seal 150 may form a coplanar side surface without a step difference.

According to one or more embodiments of the present disclosure, a display apparatus may be described as follows.

According to one or more embodiments of the present disclosure, a display apparatus may include a display panel displaying an image, a heat dissipation member disposed on one side of the display panel, and a printed circuit board disposed on one side of the heat dissipation member, wherein the heat dissipation member may include a first portion overlapping the printed circuit board, and a second portion disposed in an area spaced apart from the printed circuit board at a certain interval.

According to one or more embodiments of the present disclosure, the heat dissipation member may include a plurality of partition walls, and a plurality of spaces divided by the plurality of partition walls.

According to one or more embodiments of the present disclosure, the display apparatus may further include a third portion between the first portion and the second portion. The first portion may be a high-temperature region of the display apparatus, and the second portion is a low-temperature region of the display apparatus.

According to one or more embodiments of the present disclosure, the inside of the heat dissipation member may be in a vacuum and contain a working fluid.

According to one or more embodiments of the present disclosure, the working fluid may be vaporized in the first portion to change the phase into vapor, and the vapor may be moved to the third portion through the second portion due to the pressure difference.

According to one or more embodiments of the present disclosure, the heat dissipation member may include at least two heat dissipation members.

According to one or more embodiments of the present disclosure, the heat dissipation member may have a “U” shape.

According to one or more embodiments of the present disclosure, the heat dissipation member may have an “L” shape and include at least two heat dissipation members.

According to one or more embodiments of the present disclosure, the display panel includes a light emitting element and the light emitting element may include an inorganic material.

According to one or more embodiments of the present disclosure, the display apparatus may further include a plate disposed between the display panel and the heat dissipation member.

According to one or more embodiments of the present disclosure, the plate may include a bead or rib.

According to one or more embodiments of the present disclosure, the heat dissipation member may be disposed on the rear surface of the plate.

According to one or more embodiments of the present disclosure, the heat dissipation member may be disposed between the plate and the printed circuit board.

According to one or more embodiments of the present disclosure, the plate may include a first plate on the rear surface of the display panel, and a second plate on the rear surface of the first plate. The second plate may be spaced apart from the printed circuit board.

According to one or more embodiments of the present disclosure, the display apparatus may further include a shield member disposed on the printed circuit board. The shield member may include a hole.

According to one or more embodiments of the present disclosure, a display apparatus may include a plurality of display modules arranged on the same plane. Each of the display modules may include a display panel having a front surface on which a plurality of light emitting elements are disposed and a rear surface opposite to the front surface, a printed circuit board disposed on the rear surface of the display panel, and a heat exchange tube that at least partially overlaps the printed circuit board.

According to one or more embodiments of the present disclosure, the heat exchange tube may include a first portion overlapping the printed circuit board, a second portion disposed in an area spaced apart from the printed circuit board at a certain interval, and a third portion configured to connect the first portion and the second portion.

The display apparatus may further include a first plate disposed on the rear surface of the display panel. At least a portion of the heat exchange tube may be disposed between the first plate and the printed circuit board.

According to one or more embodiments of the present disclosure, the display apparatus may further include a second plate disposed on the rear surface of the display panel, so that at least a portion of the second plate is disposed between the printed circuit board and the display panel. At least a portion of the heat exchange tube may overlap the printed circuit board between the second plate and the printed circuit board.

According to one or more embodiments of the present disclosure, it may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc.

Additionally, the display apparatus according to one or more embodiments of the present disclosure may be applied to organic light emitting lighting devices or inorganic light emitting lighting devices.

Although the embodiments of the present disclosure have been described in more detail with reference to the accompanying drawings, the present disclosure is not necessarily limited to these embodiments, and various modifications may be made without departing from the technical spirit of the present disclosure.

Accordingly, the embodiments disclosed in the present disclosure are not intended to limit the technical idea of the present disclosure, but are for illustrative purposes, and the scope of the technical idea of the present disclosure is not limited by these embodiments.

Therefore, it should be understood that the embodiments described above are illustrative in all respects and not limiting.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel configured to display images;
a heat dissipation member disposed on at least one side of the display panel; and
a printed circuit board disposed on at least one side of the heat dissipation member,
wherein the heat dissipation member includes a first portion overlapping the printed circuit board and a second portion disposed in an area spaced apart from the printed circuit board at an interval.

2. The display apparatus according to claim 1, wherein the heat dissipation member includes a plurality of partition walls and a plurality of spaces each among partition walls of the plurality of partition walls.

3. The display apparatus according to claim 1, wherein the heat dissipation member further includes:
a third portion between the first portion and the second portion,
wherein the first portion is a high-temperature region of the display apparatus, and the second portion is a low-temperature region of the display apparatus.

4. The display apparatus according to claim 3, wherein an inside portion of the heat dissipation member is in a vacuum and contains a working fluid.

5. The display apparatus according to claim 4, wherein in operation, the working fluid is vaporized in the first portion to change a phase into vapor, and the vapor is moved to the third portion through the second portion due to a pressure difference.

6. The display apparatus according to claim 5, wherein the heat dissipation member includes at least two heat dissipation members.

7. The display apparatus according to claim 1, wherein the heat dissipation member has a “U” shape.

8. The display apparatus according to claim 1, wherein the heat dissipation member includes at least two heat dissipation members, each having an “L” shape.

9. The display apparatus according to claim 1, wherein the display panel includes a light emitting element and the light emitting element includes an inorganic material.

10. The display apparatus according to claim 1, further comprising:
a plate disposed between the display panel and the heat dissipation member.

11. The display apparatus according to claim 10, wherein the plate includes a bead or a rib.

12. The display apparatus according to claim 10, wherein the heat dissipation member is disposed on a rear surface of the plate.

13. The display apparatus according to claim 10, wherein the heat dissipation member is disposed between the plate and the printed circuit board.

14. The display apparatus according to claim 10, wherein the plate includes:
a first plate on a front surface of the display panel; and
a second plate on a rear surface of the first plate, and
wherein the second plate is spaced apart from the printed circuit board.

15. The display apparatus according to claim 1, further comprising:
a shield member disposed on the printed circuit board,
wherein the shield member includes a hole.

16. A display apparatus comprising:
a plurality of display modules arranged on a same plane,
wherein each of the display modules includes:
a display panel having a front surface on which a plurality of light emitting elements are disposed and a rear surface opposite to the front surface;
a printed circuit board disposed on the rear surface of the display panel; and
a heat exchange tube that at least partially overlaps the printed circuit board.

17. The display apparatus according to claim 16, wherein the heat exchange tube includes:
a first portion overlapping the printed circuit board;
a second portion disposed in an area spaced apart from the printed circuit board at an interval; and
a third portion between the first portion and the second portion.

18. The display apparatus according to claim 16, further comprising:
a first plate disposed on the rear surface of the display panel,
wherein at least a portion of the heat exchange tube is disposed between the first plate and the printed circuit board.

19. The display apparatus according to claim 16, further comprising:
a second plate disposed on the rear surface of the display panel, so that at least a portion of the second plate is disposed between the printed circuit board and the display panel,
wherein the at least a portion of the heat exchange tube overlaps the printed circuit board between the second plate and the printed circuit board.
